(19) United States
(12) Patent Application Publication
(10) Pub. No.: US 2025/0210701 A1
(43) Pub. Date: Jun. 26, 2025

(54) COMPOSITE SOLID ELECTROLYTE LAYER, METHOD FOR PREPARING THE SAME, AND ALL-SOLID SECONDARY BATTERY

(71) Applicant: SEOUL NATIONAL UNIVERSITY R&DB FOUNDATION, Seoul (KR)

(72) Inventors: Kisuk KANG, Seoul (KR); Sunyoung LEE, Seoul (KR)

(21) Appl. No.: 19/075,315

(22) Filed: Mar. 10, 2025

Related U.S. Application Data
(63) Continuation of application No. PCT/KR2023/012617, filed on Aug. 25, 2023.

(30) Foreign Application Priority Data
Feb. 21, 2023 (KR) 10-2023-0022761

(51) Int. Cl. H01M 10/0562; C23C 14/06; C23C 14/18; C23C 14/24; H01M 10/0525; H01M 10/42

(52) U.S. Cl. CPC H01M 10/0562; C23C 14/0694; C23C 14/18; C23C 14/24; H01M 10/0525; H01M 10/4235; H01M 2300/0068; H01M 2300/0071; H01M 2300/0094

(57) ABSTRACT

Provided is a composite solid electrolyte layer having excellent power performance and long-term cycle stability. An embodiment of the present invention provides a composite solid electrolyte layer including a solid electrolyte layer containing a solid electrolyte, an electron blocking layer disposed on at least one surface of the solid electrolyte layer, and a lithiophilic layer disposed on the electron blocking layer.

### CROSS-REFERENCE TO RELATED APPLICATIONS

This application is a Continuation of Application No. PCT/KR2023/012617, filed on Aug. 25, 2023, which in turn claims the benefit of Korean Patent Application No. 10-2023-0022761, filed on Feb. 21, 2023. The entire disclosures of all these applications are hereby incorporated by reference.

### TECHNICAL FIELD

The present invention relates to a composite solid electrolyte layer, and more particularly, to a composite solid electrolyte layer, a method for preparing the same, and an all-solid secondary battery.

### BACKGROUND ART

All-solid secondary batteries do not include combustible organic solvents, and may thus have significantly reduced chances of causing fires or explosions even when short circuits occur. Therefore, the all-solid batteries provide far greater safety and higher energy than density lithium-ion batteries using electrolytes.

Meanwhile, a dendrite indicates a tree-like structure of crystals that accumulate on a surface of a negative electrode during a charging process of secondary batteries. When dendrites are formed and grow, battery performance is reduced, and when the dendrites continue to grow, cracks may be caused in solid electrolytes, and properties of an interface between lithium metal and a solid electrolyte layer are degraded. In addition, the generation of cracks in solid electrolyte layers causes short circuits in all-solid secondary batteries.

### DISCLOSURE OF THE INVENTION

### Technical Problem

The present invention provides a complex solid electrolyte layer capable of addressing an issue that a path for electrons created when cracks occur in a solid electrolyte layer due to dendrites allows the electrons to move from a negative electrode to the solid electrolyte layer and thus react with lithium ions, resulting in generation and growth of lithium metal nucleus.

The present invention also provides a composite solid electrolyte layer having excellent long-term cycle stability and durability.

The present invention also provides a composite solid electrolyte layer capable of preventing degradation with an increase in critical current density of an electrolyte layer even when a high current density is applied to lithium metal, and capable of achieving specific capacity at the same level as an initial level even when the number of cycles increases.

The present invention also provides a method for preparing the composite solid electrolyte layer.

The present invention also provides an all-solid secondary battery including the composite solid electrolyte layer.

Aspects of the present invention are not limited to the above-described aspects, and other tasks and benefits of the present invention which are not described may be appreciated from the following descriptions, and more clearly appreciated from embodiment of the present invention. Further, it will be easily appreciated that the aspects and benefits of the present invention may be practiced by features recited in the appended claims and a combination thereof.

### Technical Solution

An embodiment of the present invention to achieve the aspects described above provides a composite solid electrolyte layer including a solid electrolyte layer containing a solid electrolyte, an electron blocking layer disposed on at least one surface of the solid electrolyte layer, and a lithiophilic layer disposed on the electron blocking layer.

According to an embodiment, the solid electrolyte may be at least any one selected from an oxide-based solid electrolyte and a sulfide-based solid electrolyte.

According to an embodiment, the oxide-based solid electrolyte may be at least one selected from Li_{1+x+y}AlₓTi₂₋ₓSi_{y}P_{3-y}O12 (0<x<2, 0≤y<3), Li₃PO₄, LiₓTi_{y}(PO₄)₃ (0<x<2, 0<y<3), LiₓAl_{y}Ti_{z} (PO₄)₃ (0<x<2, 0<y<1, 0<z<3), Li_{1+x+y}(Al, Ga)ₓ(Ti, Ge)₂₋ₓSi_{y}P_{3-y}O₁₂ (0≤x≤1 0≤y≤1), LiₓLa_{y}TiO₃ (0<x<2, 0<y<3) , Li₂O, LiOH, Li₂CO₃, LiAlO₂, Li₂O—Al₂O₃—SiO₂—P₂O₅—TiO₂GeO₂, and Li₃₊ₓLa₃M₂O₁₂ (M=Te, Nb, or Zr, and x is an integer of 1 to 10).

The oxide-based solid electrolyte may include a garnet-type solid electrolyte.

For example, the garnet-type solid electrolyte may include a compound represented by Formula 1 below.

(LiₓM1_{y}) (Laₐ₁M2ₐ₂)_{3-δ}(Zr_{b1}M3_{b2})_{2-ω}O_{12-z}X_{z} [Formula 1]

In Formula 1 above, M1 may be any one selected from the group consisting of hydrogen (H), iron (Fe), gallium (Ga), aluminum (Al), boron (B), beryllium (Be), and a combination thereof, M2 may be any one selected from the group consisting of barium (Ba), calcium (Ca), strontium (Sr), yttrium (Y), bismuth (Bi), praseodymium (Pr), neodymium (Nd), actinium (Ac), samarium (Sm), gadolinium (Gd), and a combination thereof, M3 may be any one selected from the group consisting of hafnium (Hf), tin (Sn), niobium (Nb), titanium (Ti), vanadium (V), chromium (Cr), manganese (Mn), cobalt (Co), nickel (Ni), copper (Cu), molybdenum (Mo), tungsten (W), tantalum (Ta), magnesium (Mg), technetium (Tc), ruthenium (Ru), palladium (Pd), iridium (Ir), scandium (Sc), cadmium (Cd), indium (In), antimony (Sb), tellurium (Te), thallium (Tl), platinum (Pt), silicon (Si), aluminum (Al), and a combination thereof, and 6≤x≤8, 0≤y<2, −0.2≤δ≤0.2, −0.2≤ω≤0.2, and 0≤z≤2 may be satisfied, a1+a2=1, 0<a1≤1, 0≤a2<1, b1+b2=1, 0<b1<1, and 0<b2<1 may be satisfied, and X may be a monovalent anion, a divalent anion, or a trivalent anion.

For example, the garnet-type solid electrolyte may include a compound represented by Formula 2 below.

Li₃₊ₓLa₃Zr₂₋ₐMₐO₁₂ [Formula 2]

In Formula 2 above, M is any one selected from the group consisting of Al, Ga, In, Si, Ge, Sn, Sb, Bi, Sc, Y, Ti, Hf, V, Nb, Ta, W, and a combination thereof, x is an integer of 1 to 10, and 0≤a<2 is satisfied.

According to an embodiment, the sulfide-based solid electrolyte may include at least one selected from Li₂S—P₂S₅, Li₂S—P₂S₅—Liₓ (where X is a halogen element), Li₂S—P₂S₅—Li₂O, Li₂S—P₂S₅—Li₂O—LiI, Li₂S—SiS₂, Li₂S—SiS₂—LiI, Li₂S—SiS₂—LiBr, Li₂S—SiS₂—LiCl, Li₂S—SiS₂—B₂S₃—LiI, Li₂S—SiS₂P₂S₅LiI, Li₂S—B₂S₃, Li₂SP₂S₅—ZₘSₙ (where m and n are positive numbers, and Z is one of Ge, Zn, or Ga), Li₂S—GeS₂, Li₂S—SiS₂—Li₃PO₄, Li₂S—SiS₂—LiₚMO_{q} (where p and q are positive numbers, and M is one of P, Si, Ge, B, Al, Ga, or In), Li₇₋ₓPS₆₋ₓClₓ (0<x<2), Li₇₋ₓPS₆₋ₓBrₓ (0<x<2), and Li₇₋ₓPS₆₋ₓIₓ (0<x<2).

According to an embodiment, the electron blocking layer may include an inorganic compound, and more specifically may include at least any one selected from the group consisting of a halide-based compound and a metal oxide.

For example, the halide-based compound may be at least one or at least two selected from the group consisting of LiF, NaF, KF, RbF, CsF, FrF, MgF₂, CaF₂, SrF₂, BaF₂, LiCl, NaCl, KCl, RbCl, CsCl, and FrCl.

For example, the metal oxide may be at least one or at least two selected from the group consisting of Li₂O, Li₂O₂, Na₂O, K₂O, Rb₂O, Rb₂O₂, Cs₂O, Cs₂O₂, LiAlO₂, LiBO₂, LiTaO₃, LiNbO₃, LiWO₄, Li₂CO, NaWO₄, KAlO₂, K₂SiO₃, B₂O₅, Al₂O₃, and SiO₂.

According to an embodiment, the electron blocking layer may have a thickness of 10 to 200 nm.

According to an embodiment, the lithiophilic layer may include a lithium alloy forming material. For example, the lithium alloy forming material may include one selected from the group consisting of silver (Ag), gold (Au), aluminum (Al), calcium (Ca), zinc (Zn), magnesium (Mg), and potassium (K), a mixture of two or more thereof, or an alloy of two or more thereof.

According to an embodiment of the present invention, lithium diffusivity in the lithiophilic layer may be 10⁻¹⁰ cm²/s or greater, specifically 10⁻⁶ cm²/s or greater, at 25° C.

According to an embodiment, the lithiophilic layer may have a thickness of 10 to 200 nm.

Another embodiment of the present invention to achieve the aspects described above provides a method for preparing a composite solid electrolyte layer which includes (S1) forming an electron blocking layer on at least one surface of a solid electrolyte layer containing a solid electrolyte, and (S2) forming a lithiophilic layer on one surface of the electron blocking layer of the solid electrolyte layer on which the electron blocking layer is formed.

According to an embodiment, (S1) and (S2) above may be performed through the same deposition process or different deposition processes.

According to an embodiment, (S1) and (S2) above may each independently performed through any one method selected from the group consisting of physical vapor deposition, chemical vapor deposition, and a combination thereof.

According to an embodiment, (S1) and (S2) above may be performed through a process of thermal evaporation deposition.

According to an embodiment, (S1) and (S2) above may each independently include depositing at least any one thin film of the electron blocking layer and the lithiophilic layer at a deposition rate of 0.1 to 1.0 Ås⁻¹, and annealing the deposited thin film at 400 to 800° C. for 1 to 3 hours.

Another embodiment of the present invention to achieve the aspects described above provides an all-solid secondary battery including the composite solid electrolyte layer, a negative electrode disposed on one surface of the composite solid electrolyte layer, and a positive electrode disposed on the other surface of the composite solid electrolyte layer, wherein the negative electrode is in contact with the lithiophilic layer.

According to an embodiment, the negative electrode may include Li metal.

According to an embodiment, the positive electrode may be impregnated into an ionic liquid.

The means for addressing the above tasks do not present all the characteristics of the present invention. The various characteristics of the present invention and benefits and effects thereof may be understood in more detail with reference to specific examples below.

### Advantageous Effects

According to an aspect of the present invention, when an electron blocking layer disposed on at least one surface of a solid electrolyte layer, and a lithiophilic layer disposed on the electron blocking layer are included, electrons are prevented from moving to an electrolyte layer from a negative electrode effectively, and accordingly, generation of lithium metal nucleus may be effectively delayed inside a cell to effectively prevent short circuits from occurring.

In addition to the effects described above, specific effects of the present invention have been described in the above detailed description of the embodiments of the present invention.

### BRIEF DESCRIPTION OF THE DRAWINGS

FIG. 1A is a schematic view of a typical negative electrode-solid electrolyte layer assembly and FIG. 1B is a schematic view of a negative electrode-solid electrolyte layer assembly according to an embodiment of the present invention;

FIG. 2A is an image of transmission electron microscopy (TEM) of a composite solid electrolyte layer according to Example 1;

FIG. 2B is elemental mapping of La in the composite solid electrolyte layer according to Example 1;

FIG. 2C is elemental mapping of F in the composite solid electrolyte layer according to Example 1;

FIG. 2D is elemental mapping of Ag in the composite solid electrolyte layer according to Example 1;

FIG. 3 is an actual image of the composite solid electrolyte layer according to Example 1 to demonstrate lithiophilic properties of an LiF thin film;

FIG. 4A is an image of high-resolution transmission electron microscopy (HRTEM) of the composite solid electrolyte layer according to Example 1;

FIG. 4B is a fast Fourier transform (FFT) pattern of LiF, LLZTO region 1, and LLZTO region 2 of the composite solid electrolyte layer according to Example 1;

FIG. 4C is an inverse FFT pattern of the LiF region of the composite solid electrolyte layer according to Example 1;

FIG. 5 shows the results of X-ray photoelectron spectroscopy (XPS) analysis of the composite solid electrolyte layer according to Example 1;

FIG. 6A is a profile of the current (mA) over time on cells including solid electrolyte layers according to Comparative Examples 1 and 3 when an applied voltage is 1 V at room temperature;

FIG. 6B is a profile of electrical conductivity (S/cm) according to voltage on cells including the solid electrolyte layers according to Comparative Examples 1 and 3;

FIG. 6C is a profile of electrical conductivity (S/cm) according to temperature on cells including the solid electrolyte layers according to Comparative Examples 1 and 3;

FIG. 7A is an image of ex situ backscattered electron detector (BSD)-SEM of an electrolyte layer of a lithium symmetric cell including an electrolyte layer of Comparative Example 2 before electrical short circuits;

FIG. 7B is an image of ex situ backscattered electron detector (BSD)-SEM of an electrolyte layer of a lithium symmetric cell including an electrolyte layer of Comparative Example 2 after electrical short circuits;

FIG. 7C is an image of ex situ backscattered electron detector (BSD)-SEM of a lithium symmetric cell including an electrolyte layer of Example 1 before electrical short circuits;

FIG. 7D is an image of ex situ backscattered electron detector (BSD)-SEM of a lithium symmetric cell including an electrolyte layer of Example 1 after electrical short circuits;

FIG. 8 is an SEM image of an interface between lithium metal and a composite solid electrolyte layer in a negative electrode-electrolyte layer assembly of Example 1;

FIG. 9 is a Nyquist plot of electrochemical impedance spectroscopy (EIS) analysis for lithium symmetric cells according to Comparative Examples 1 and 2 and Example 1;

FIG. 10A shows critical current density of a lithium symmetric cell of Comparative Example 2 with an increase in current density;

FIG. 10B shows critical current density of a lithium symmetric cell of Example 1 with an increase in current density;

FIG. 11A shows the results of cycle stability evaluation according to constant current charge/discharge method on the lithium symmetric cells of Comparative Example 2 and Example 1 when the current density is 0.2 mA/cm² for 0.5 hours at 25° C., and constant current tests were measured using potentio-galvanostat (WBCS 3000, WonATech);

FIG. 11B shows the results of cycle stability evaluation according to constant current charge/discharge method on the lithium symmetric cell of Example 1 when the current density is 0.5 mA/cm² at 25° C.;

FIG. 12A is a voltage profile according to specific capacity on a hybrid full cell of Example 1 at 60° C. when the charge/discharge rate (C-rate) is different;

FIG. 12B shows specific capacity (mA·h/g) according to the number of cycles on hybrid full cells of Comparative Examples 1 and 2 and Example 1 at 60° C. when the charge/discharge rate (C-rate) is different;

FIG. 12C shows cycle performance of the hybrid full cell of Example 1 when 1.0 C is applied to a positive electrode and 0.5 mA/cm² (yellow & dark gray) is applied to a negative electrode, and 2.0 C is applied to a positive electrode and 1.0 mA/cm² (green & light gray) is applied to a negative electrode;

FIG. 12D shows cycle performance of a hybrid full cell of modified Example 1 when 0.5 C is applied to a positive electrode and 0.25 mA/cm² is applied to a negative electrode; and

FIG. 12E compares a typical hybrid full cell and the hybrid full cell of Example 1.

### MODE FOR CARRYING OUT THE INVENTION

Herein, the numerical range indicated by using “to” represents a numerical range including the values described therebefore and thereafter as a lower limit and an upper limit, respectively. When a plurality of numerical values each for the upper and lower limits of any numerical range are disclosed, the numerical range disclosed herein may be understood as any numerical range in which any one of the plurality of lower limit values and any one of the plurality of upper limit values are each set as a lower limit and an upper limit.

Hereinafter, principles of preferred embodiments of the present invention will be described in detail with reference to the accompanying drawings and descriptions. However, the drawings shown below and the following descriptions are for preferred methods among various methods, for effectively describing characteristics of the present invention, and the present invention is not limited only to the following drawings and descriptions.

Meanwhile, although terms such as first, second, and the like may be used herein to describe various elements, these terms are used merely to distinguish one element from another element. For example, a first element may be referred to as a second element, and similarly, a second element may be referred to as a first element.

The singular forms are intended to include the plural forms as well, unless the context clearly indicates otherwise. As used herein, it should be understood that the terms “comprise” or “have” are intended to specify the presence of stated features, integers, processes, operations, elements, components, or combinations thereof, but do not preclude the presence or addition of one or more other features, integers, processes, operations, elements, components, or combinations thereof.

Unless defined otherwise, all the terms used herein, including technical or scientific terms, may have the same meanings as those commonly understood by those skilled in the art. Terms that are defined in a commonly used dictionary should be construed as having meanings consistent with the meanings in the context of the related art, and should not be construed as having an ideal or overly formal meaning unless explicitly defined herein.

An embodiment of the present invention provides a composite solid electrolyte layer including a solid electrolyte layer containing a solid electrolyte, an electron blocking layer disposed on at least one surface of the solid electrolyte layer, and a lithiophilic layer disposed on the electron blocking layer.

Previously, in all-solid secondary batteries, a dendrite which is a tree-like structure of crystals that accumulate on a surface of a negative electrode during a charging process caused cracks in the solid electrolyte layer. When cracks occurred in the solid electrolyte layer, a path for electrons was created, allowing the electrons to move from a negative electrode to the solid electrolyte layer and thus to react with lithium ions, resulting in generation and growth of lithium metal nucleus. When the generation and growth of lithium metal nucleus in the solid electrolyte layer took place, consequently, short circuits occurred, causing degradation in electrochemical performance, cycle stability, and durability.

According to an aspect of the present invention, when an electron blocking layer disposed on at least one surface of a solid electrolyte layer, and a lithiophilic layer disposed on the electron blocking layer are included, electrons are prevented from moving to an electrolyte layer from a negative electrode effectively, and accordingly, generation of lithium metal nucleus may be effectively delayed inside the solid electrolyte to effectively prevent short circuits of a cell from occurring. When the lithiophilic layer is included but the electron blocking layer is not included, electrons may move from the negative electrode to the electrolyte layer, resulting in a risk of short circuits and failing to reach a sufficient level of critical current density, thereby showing degradation in cell stability and cycle stability. When the electron blocking layer is included but the lithiophilic layer is not included, the wettability on lithium may be reduced, causing degradation in interfacial adhesion between the negative electrode and the electrolyte layer and uneven diffusion of lithium ions.

Hereinafter, components of the present invention will be described in more detail.

### 1. Composite Solid Electrolyte Layer

A composite solid electrolyte layer according to the present invention facilitates the movement of lithium ions and includes a solid electrolyte layer that physically and electrically separates a negative electrode and a positive electrode. Specifically, the solid electrolyte layer includes a solid electrolyte.

For example, the solid electrolyte may be at least any one selected from an oxide-based solid electrolyte and a sulfide-based solid electrolyte. According to an example, the oxide-based solid electrolyte may be at least one selected from Li_{1+x+y}AlₓTi₂₋ₓSi_{y}P_{3-y}O12 (0<x<2, 0≤y<3), Li₃PO₄, LiₓTi_{y}(PO₄)₃ (0<x<2, 0<y<3), LiₓAl_{y}Ti_{z}(PO₄)₃ (0<x<2, 0<y<1, 0<z<3), Li_{1+x+y}(Al, Ga)ₓ(Ti, Ge)₂₋ₓSi_{y}P_{3-y}O₁₂ (0≤x≤1 0≤y≤1), LiₓLa_{y}TiO₃ (0<x<2, 0<y<3), Li₂O, LiOH, Li₂CO₃, LiAlO₂, Li₂O—Al₂O₃—SiO₂—P₂O₅—TiO₂—GeO₂, and Li₃₊ₓLa₃M₂O₁₂ (M=Te, Nb, or Zr, and x is an integer of 1 to 10).

According to an embodiment of the present invention, the oxide-based solid electrolyte may include a garnet-type solid electrolyte.

For example, the garnet-type solid electrolyte may include a compound represented by Formula 1 below.

(LiₓM1_{y})(Laₐ₁M2ₐ₂)_{3-δ}(Zr_{b1}M3_{b2})_{2-ω}O_{12-z}X_{z} [Formula 1]

In Formula 1 above, M1 is any one selected from the group consisting of hydrogen (H), iron (Fe), gallium (Ga), aluminum (Al), boron (B), beryllium (Be), and a combination thereof, M2 is any one selected from the group consisting of barium (Ba), calcium (Ca), strontium (Sr), yttrium (Y), bismuth (Bi), praseodymium (Pr), neodymium (Nd), actinium (Ac), samarium (Sm), gadolinium (Gd), and a combination thereof, M3 is any one selected from the group consisting of hafnium (Hf), tin (Sn), niobium (Nb), titanium (Ti), vanadium (V), chromium (Cr), manganese (Mn), cobalt (Co), nickel (Ni), copper (Cu), molybdenum (Mo), tungsten (W), tantalum (Ta), magnesium (Mg), technetium (Tc), ruthenium (Ru), palladium (Pd), iridium (Ir), scandium (Sc), cadmium (Cd), indium (In), antimony (Sb), tellurium (Te), thallium (Tl), platinum (Pt), silicon (Si), aluminum (Al), and a combination thereof, and 6≤x≤8, 0≤y<2, 0.2≤δ≤0.2, −0.2≤ω≤0.2, and 0≤z≤2 are satisfied, a1+a2=1, 0<a1≤1, 0≤a2<1, b1+b2=1, 0<b1<1, and 0<b2<1 are satisfied, and X is a monovalent anion, a divalent anion, or a trivalent anion.

For example, the garnet-type solid electrolyte may include a compound represented by Formula 2 below.

Li₃₊ₓLa₃Zr₂₋ₐMₐO₁₂ [Formula 2]

In Formula 2 above, M is any one selected from the group consisting of Al, Ga, In, Si, Ge, Sn, Sb, Bi, Sc, Y, Ti, Hf, V, Nb, Ta, W, and a combination thereof, x is an integer of 1 to 10, and 0≤a<2 is satisfied.

According to an embodiment of the present invention, the oxide-based solid electrolyte may be prepared by contacting precursors in stoichiometric amounts to form a mixture, and thermally treating the mixture. For example, the contacting may include milling, such as ball milling, or grinding. The mixture of the precursors combined in stoichiometric amounts may be subjected to a first thermal treatment under an oxidizing atmosphere to prepare a first thermal treatment product. The first thermal treatment may be performed at a temperature of 1,000° C. or less for about 1 hour to about 36 hours.

The first thermal treatment product may then be ground. The first thermal treatment product may be ground through wet grinding or dry grinding. For example, the wet grinding may be performed by mixing the first thermal treatment product with a solvent such as methanol and milling the mixture using, for example, a ball mill for 0.5 hour to 10 hours. The dry grinding may be performed using, for example, a ball mill without solvents. The ground first thermal treatment product may have a particle diameter of 0.1 μm to 10 μm, or 0.1 μm to 5 μm. The ground first thermal treatment product may be dried. The ground first thermal treatment product may be shaped in pellet form following mixing with a binder solution, or may be shaped in pellet form by simply being pressed at a pressure of 1 ton to 10 tons. The shaped product in pellet form may be subjected to a second thermal treatment at a temperature of less than 1,000° C. for 1 hour to 36 hours. Through the second thermal treatment, the solid electrolyte layer, which is a sintered product, is obtained. The second thermal treatment may be performed, for example, at a temperature of 550 to 1,200° C. For example, the first thermal treatment takes 1 hour to 36 hours. The second thermal treatment temperature for obtaining the sintered product is greater than the first thermal treatment temperature. For example, the second thermal treatment temperature may be 10° C. or greater, 20° C. or greater, 30° C. or greater, or 50° C. or greater than the first thermal treatment temperature.

For example, the sulfide-based solid electrolyte may include at least one selected from Li₂S—P₂S₅, Li₂S—P₂S₅—Li_{X} (where X is a halogen element), Li₂S—P₂S₅—Li₂O, Li₂S—P₂S₅—Li₂O—LiI, Li₂S—SiS₂, Li₂S—SiS₂—LiI, Li₂S—SiS₂—LiBr, Li₂S—SiS₂—LiCl, Li₂S—SiS₂—B₂S₃—LiI, Li₂S—SiS₂—P₂S₅—LiI, Li₂S—B₂S₃, Li₂SP₂S₅—ZₘSₙ (where m and n are positive numbers, and Z is one of Ge, Zn, or Ga), Li₂S—GeS₂, Li₂S—SiS₂—Li₃PO₄, Li₂S—SiS₂—LiₚMO_{q} (where p and q are positive numbers, and M is one of P, Si, Ge, B, Al, Ga, or In), Li₇₋ₓPS₆₋ₓClₓ (0<x<2), Li₇₋ₓPS₆₋ₓBrₓ (0<x<2), and Li₇₋ₓPS₆₋ₓIₓ (0<x<2).

The electron blocking layer according to the present invention may effectively block electrons from moving from the negative electrode to the electrolyte layer.

The electron blocking layer according to the present invention may be disposed on at least one surface of the solid electrolyte layer, specifically disposed on one surface of the solid electrolyte layer, and more specifically disposed directly on the solid electrolyte layer.

According to an embodiment of the present invention, the electron blocking layer may include an inorganic compound to effectively block electrons from moving from the negative electrode to the electrolyte layer.

Specifically, the inorganic compound may include at least any one selected from the group consisting of a halide-based compound and a metal oxide. For example, the halide-based compound may be at least one or at least two selected from the group consisting of LiF, NaF, KF, RbF, CsF, FrF, MgF₂, CaF₂, SrF₂, BaF₂, LiCl, NaCl, KCl, RbCl, CsCl, and FrCl. For example, the metal oxide may be at least one or at least two selected from the group consisting of Li₂O, Li₂O₂, Na₂O, K₂O, Rb₂O, Rb₂O₂, Cs₂O, Cs₂O₂, LiAlO₂, LiBO₂, LiTaO₃, LiNbO₃, LiWO₄, Li₂CC, NaWO₄, KAlO₂, K₂SiO₃, B₂O₅, Al₂O₃, and SiO₂.

The electron blocking layer according to the present invention may have a thickness of 10 to 200 nm, 70 to 200 nm, 80 to 190 nm, 90 to 180 nm, or 100 to 170 nm. When the thickness of the electron blocking layer satisfies the above numerical range, the movement of electrons from the negative electrode to the electrolyte layer may be effectively blocked and the interfacial adhesion between the negative electrode and the electrolyte layer may be excellent.

The lithiophilic layer according to the present invention may improve the wettability on lithium to increase the interfacial adhesion between the negative electrode and the electrolyte layer, and to allow uniform diffusion of lithium ions. According to an aspect of the present invention, when an electron blocking layer disposed on at least one surface of a solid electrolyte layer, and a lithiophilic layer disposed on the electron blocking layer are included, electrons are prevented from moving to an electrolyte layer from a negative electrode effectively, and accordingly, generation of lithium metal nucleus may be effectively delayed inside a cell to effectively prevent short circuits from occurring. When the lithiophilic layer is included but the electron blocking layer is not included, electrons may move from the negative electrode to the electrolyte layer, resulting in a risk of short circuits and failing to reach a sufficient level of critical current density, thereby showing degradation in cell stability and cycle stability. When the electron blocking layer is included but the lithiophilic layer is not included, the wettability on lithium causing degradation in interfacial adhesion may be reduced, between the negative electrode and the electrolyte layer and uneven diffusion of lithium ions.

The lithiophilic layer according to the present invention may be disposed on the electron blocking layer, and specifically may be disposed directly on the electron blocking layer. That is, the electron blocking layer may be interposed between the solid electrolyte layer and the lithiophilic layer.

The lithiophilic layer according to the present invention may include a lithium alloy forming material capable of forming an alloy with lithium. Specifically, the lithiophilic layer includes a lithium alloy forming material capable of forming an alloy with the lithium, and may thus improve the wettability on lithium to increase the interfacial adhesion between the negative electrode and the electrolyte layer, and to allow uniform diffusion of lithium ions.

For example, the lithium alloy forming material may include one selected from the group consisting of silver (Ag), gold (Au), aluminum (Al), calcium (Ca), zinc (Zn), magnesium (Mg), and potassium (K), a mixture of two or more thereof, or an alloy of two or more thereof.

According to an embodiment of the present invention, lithium diffusivity in the lithiophilic layer may be 10⁻¹⁰ cm²/s or greater, 10⁻⁶ cm²/s or greater, or 0⁻⁵ cm²/s or greater, at 25° C. When the lithium diffusivity in the lithiophilic layer satisfies the above numerical range, the diffusion of lithium ions may be performed well, and also the interfacial adhesion between the negative electrode and the electrolyte layer may be sufficiently increased.

The lithiophilic layer according to the present invention may have a thickness of 10 to 200 nm, 70 to 200 nm, 80 to 190 nm, 90 to 180 nm, or 100 to 170 nm. When the thickness of the lithiophilic layer satisfies the above numerical range, and the wettability on lithium may be improved to increase the interfacial adhesion between the negative electrode and the electrolyte layer and to allow uniform diffusion of lithium ions.

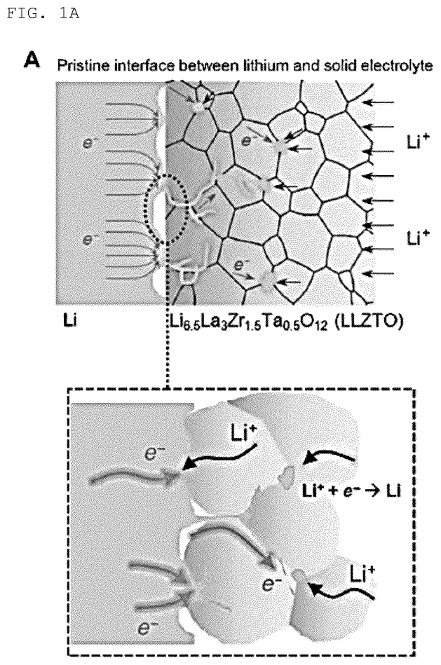

Hereinafter, components of the present invention will be described in detail with reference to FIG. 1.

FIG. 1A is a schematic view of a typical negative electrode-solid electrolyte layer assembly and FIG. 1A is a schematic view of a negative electrode-solid electrolyte layer assembly according to an embodiment of the present invention.

Referring to FIG. 1A, in the typical negative electrode-solid electrolyte layer assembly, when cracks occurred in the solid electrolyte layer, a path for electrons was created, allowing the electrons to move from a negative electrode to the solid electrolyte layer and thus to react with lithium ions, resulting in generation and growth of lithium metal nucleus. When the generation and growth of lithium metal nucleus in the solid electrolyte layer took place, consequently, short circuits occurred, causing degradation in electrochemical performance, cycle stability, and durability. Meanwhile, the negative electrode-solid electrolyte layer assembly (FIG. 1B) according to an embodiment of the present invention includes an electron blocking layer 24 disposed on at least one surface of a solid electrolyte layer 26, and a lithiophilic layer 22 disposed on the electron blocking layer 24, and thus electrons are prevented from moving to a composite solid electrolyte layer 20 from a negative electrode 10 effectively, and accordingly, generation of lithium metal nucleus may be effectively delayed inside a cell to effectively prevent short circuits from occurring.

### 2. Method for Preparing Composite Solid Electrolyte Layer

Another embodiment of the present invention may provide a method for preparing a composite solid electrolyte layer which includes (S1) forming an electron blocking layer on at least one surface of a solid electrolyte layer containing a solid electrolyte, and (S2) forming a lithiophilic layer on one surface of the electron blocking layer of the solid electrolyte layer on which the electron blocking layer is formed.

Specifically, (S1) and (S2) above may be performed through the same deposition process or different deposition processes, and more specifically, (S1) and (S2) above may be the same to increase process efficiency.

According to an embodiment of the present invention, (S1) and (S2) above may each independently be performed through any one method selected from the group consisting of physical vapor deposition, chemical vapor deposition, and a combination thereof.

According to an embodiment of the present invention, (S1) and (S2) above may be performed through a process of thermal evaporation deposition. Meanwhile, the thermal evaporation vacuum deposition process is a process of creating a vacuum chamber, heating a desired sample to convert the sample into a gaseous state, and then depositing a substrate with the resulting product to solidify the resulting product again into a thin film. When (S1) and (S2) above are performed through the thermal evaporation vacuum deposition, it may be easy to regulate the thickness of the electron blocking layer and the lithiophilic layer.

According to an embodiment of the present invention, (S1) and (S2) above may each independently include depositing at least any one thin film of the electron blocking layer and the lithiophilic layer at a deposition rate of 0.1 to 1.0 Ås⁻¹, and annealing the deposited thin film at 400 to 800° C. for 1 to 3 hours. Specifically, the additional annealing of the deposited thin film may further increase the bonding strength between the electron blocking layer and the solid electrolyte layer.

### 3. All-Solid Secondary Battery

Another embodiment of the present invention may provide an all-solid secondary including battery a composite solid electrolyte layer according to various embodiment of the present invention described above, a negative electrode disposed on one surface of the composite solid electrolyte layer, and a positive electrode disposed on the other surface of the composite solid electrolyte layer, and the negative electrode is in contact with the lithiophilic layer.

According to an embodiment of the present invention, a portion of the lithiophilic layer may be a lithium alloy layer. The lithium may form a lithium alloy with one or two metals selected from the group consisting of silver (Ag), gold (Au), aluminum (Al), calcium (Ca), zinc (Zn), magnesium (Mg), and potassium (K). This lithium alloy may be included in the lithium alloy layer described above.

Specifically, the negative electrode may include lithium metal. The negative electrode includes lithium metal, and thus has further improved interfacial bonding strength with the lithiophilic layer.

According to another embodiment of the present invention, the positive electrode may be impregnated into an ionic liquid. The positive electrode is impregnated into the ionic liquid, and thus bonding strength between the positive electrode and the electrolyte layer may be improved.

For example, the method for preparing composite a solid electrolyte layer may include preparing a negative electrode-solid electrolyte layer assembly, stacking a solid electrolyte layer so that the solid electrolyte layer is disposed between a negative electrode and a positive electrode, and then applying pressure. The pressing is, for example, roll press, uni-axial pressing, flat press, warm isotactic pressing (WIP), cold isotactic pressing (CIP), and the like, but is not necessarily limited to thereto, and any pressing used in the art is applicable. Pressure applied during the pressing is, for example, 50 MPa to 750 MPa. Time that the pressure is applied is 5 ms to 5 min. The pressing is performed, for example, at room temperature to 90° C., and at 20 to 90° C. Alternatively, pressing is performed at a high temperature of 100° C. or greater.

The all-solid secondary battery according to an embodiment may be, for example, used for high energy density mobile batteries, electric vehicles, and the like.

Hereinafter, embodiments of the present invention will be described in detail so as to be easily carried out by a person skilled in the art to which the present invention pertains, but this is only presented as an example, and the scope of the present invention is not limited to the following features.

### Manufacturing Preparation Example: Synthesis of Ta-Doped LLZTO

Ta-doped Li_{6.4}La₃Zr_{1.4}Ta_{0.6}O₁₂ (Ta-doped LLZTO) powder was synthesized using precursors of LiOH·H₂O (99.99%; Sigma-Aldrich), La₂O₃ (99.99%; Sigma-Aldrich), Ta₂O₅ (99.99%; Sigma-Aldrich), and ZrO₂ (99%; Sigma-Aldrich) through a solid-state method.

Specifically, 20 wt % of LiOH·H₂O was added to compensate for lithium (Li) that may be volatilized during a sintering process. The precursors were mixed in an alumina crucible and then calcined at 900° C. for 12 hours to synthesize cubic preliminary LLZTO. The obtained preliminary LLZTO powder was ground using a ball mill at 200 rpm for 10 hours to obtain LLZTO powder having a particle size of 5 to 10 μm.

A 10 mm pellet was prepared using the obtained LLZTO powder. The prepared pellet was mixed with 0.2 wt % of Al₂O₃ (99.9%; Sigma-Aldrich) as a sintering agent and sintered in air at 1,100° C. for 10 hours. The sintered pellet was polished using 600, 1500, and 2000 grit sandpapers to wash a surface and remove surface impurities. As a result, an LLZTO pellet having a final thickness of about 700 μm and a relative density of about 93% was synthesized.

### Preparation Example 1: Preparation of Solid Electrolyte Layer

### Example 1: Preparation of Solid Electrolyte Layer Coated With Ag/LIF Multilayer on Ta-Doped LLZTO

The LLZTO pellet of Preparation Example described above was deposited with an Ag thin film and an LiF thin film sequentially, using a vacuum thermal evaporator housed in a glove box (Korea Vacuum Tech) having a base pressure of less than 1×10⁻⁶ torr. Specifically, a surface of the LLZTO pellet of Preparation Example described above was deposited with a 150 nm thick LiF thin film at a deposition rate of 0.5 Ås⁻¹ and further annealed at 600° C. for 2 hours in an argon atmosphere to induce bonding between the LiF thin film and the LLZTO pellet. Thereafter, the LLZTO pellet on which the LiF thin film was formed at a deposition rate of 0.5 Ås⁻¹ was deposited with a 100 nm thick Ag thin film. As a result, a composite solid electrolyte layer (Ag/LiF-coated LLZTO) of Example 1 was prepared.

### Comparative Example 1: Unlike Example 1, a Case in Which an Ag/LiF Multilayer is Not Applied (Bare LLZTO)

A solid electrolyte layer was prepared in the same manner as in Example 1, except that the deposition processes of LiF thin film and Ag thin film were skipped, and finally, a bare LLZTO electrolyte layer was prepared.

### Comparative Example 2: Unlike Example 1, a Case in Which Only a Silver Thin Film was Formed on a Surface (Ag-Coated LLZTO)

A solid electrolyte layer was prepared in the same manner as in Example 1, except that an LiF thin film deposition was skipped and a silver thin film (Ag thin film) deposition was performed. As a result, a solid electrolyte layer (Ag-coated LLZTO) of Comparative Example 2 was prepared.

### Comparative Example 3: Unlike Example 1, a Case in Which Only a LiF Thin Film was Formed on a Surface (LiF-Coated LLZTO)

A solid electrolyte layer was prepared in the same manner as in Example 1, except that a silver thin film (Ag thin film) deposition was skipped and an LiF thin film (LiF thin film) deposition was performed. As a result, a solid electrolyte layer (LiF-coated LLZTO) of Comparative Example 3 was prepared.

### Experimental Example 1: TEM and EDS Images of Composite Solid Electrolyte Layer According to Example 1

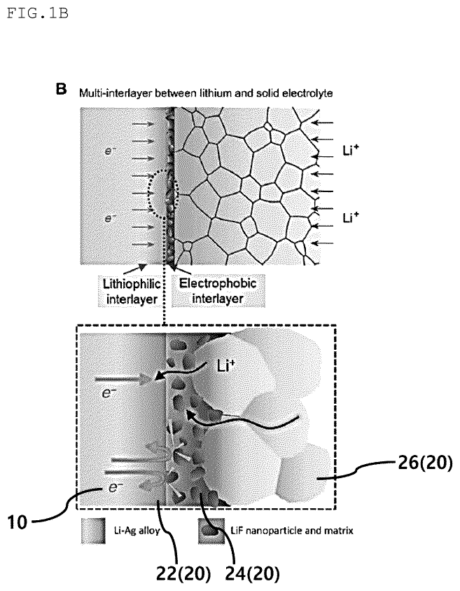

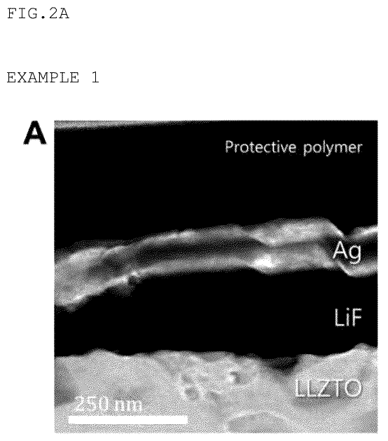

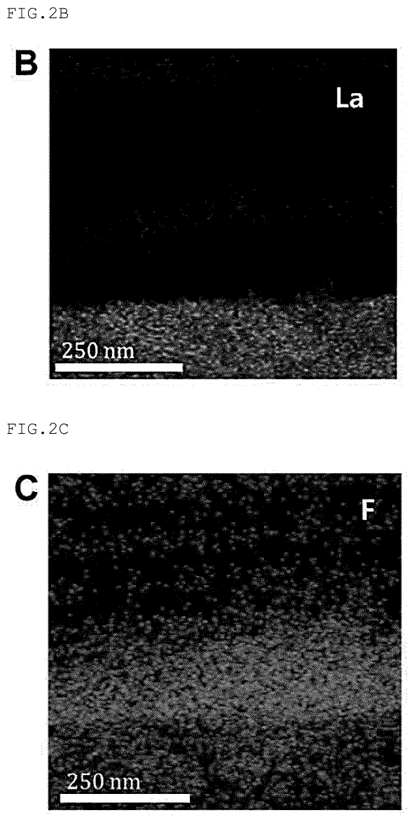

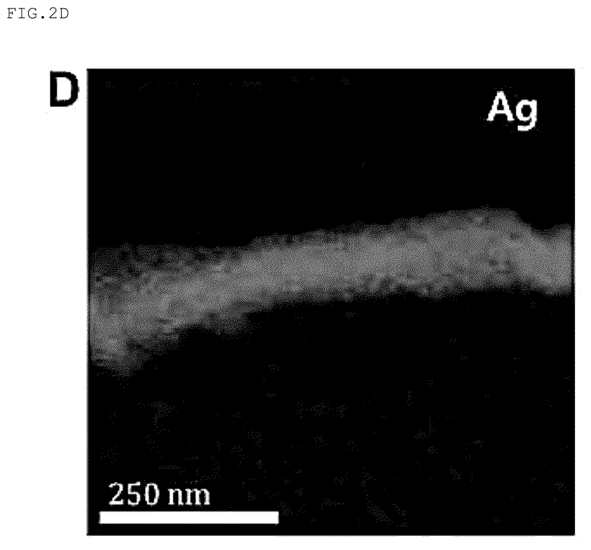

FIG. 2A is an image of transmission electron microscopy (TEM) of a composite solid electrolyte layer according to Example 1.

Referring to FIG. 2A, it is determined that the LiF thin film serving as an electron blocking layer, and the Ag thin film serving as a lithiophilic layer, are sequentially formed on the LLZTO pellet, and the coating layer formed of the LiF thin film and the Ag thin film has a thickness of about 300 nm.

FIG. 2B is elemental mapping of La in the composite solid electrolyte layer according to Example 1. FIG. 2C is elemental mapping of F in the composite solid electrolyte layer according to Example 1. FIG. 2D is elemental mapping of Ag in the composite solid electrolyte layer according to Example 1.

Referring to FIGS. 2B to 2D, it is determined that when using energy-dispersive X-ray spectroscopy (EDS), the LiF thin film serving as an electron blocking layer, and the Ag thin film serving as a lithiophilic layer in the composite solid electrolyte layer according to Example 1 are sequentially formed on the LLZTO pellet well.

### Experimental Example 2: Actual Image of Composite Solid Electrolyte Layer According to Example 1

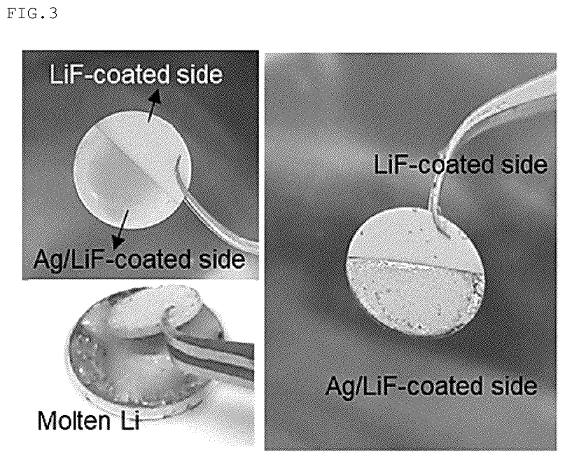

FIG. 3 is an actual image of the composite solid electrolyte layer according to Example 1 to demonstrate lithiophilic properties of an LiF thin film.

Referring to FIG. 3, half of the LLZTO pellet coated with the LiF thin film was selectively coated with the Ag thin film, and the other half of the LLZTO pellet coated with the LiF thin film was kept as is to prepare a sample.

When the prepared sample is immersed in molten lithium metal for a few seconds to determine wettability, the surface coated with the Ag/LiF thin film of the sample was completely wet with the molten lithium metal, while little lithium was observed on the surface coated with the LiF thin film. Accordingly, it may be inferred that the Ag thin film improves the wettability of lithium.

### Experimental Example 3: HRTEM Image of Composite Solid Electrolyte Layer According to Example 1

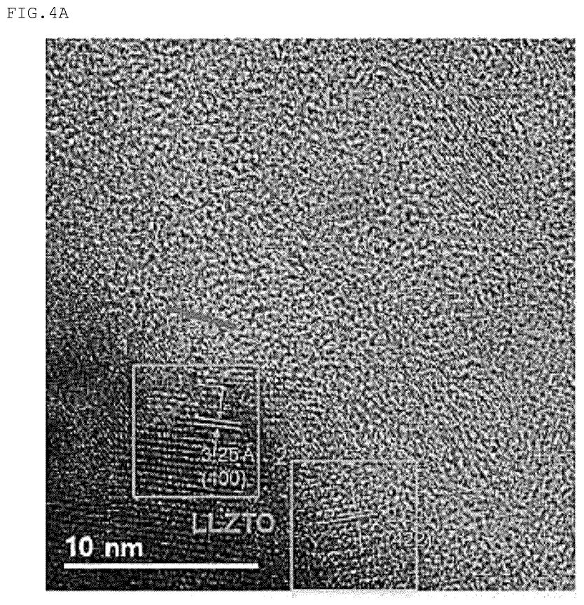

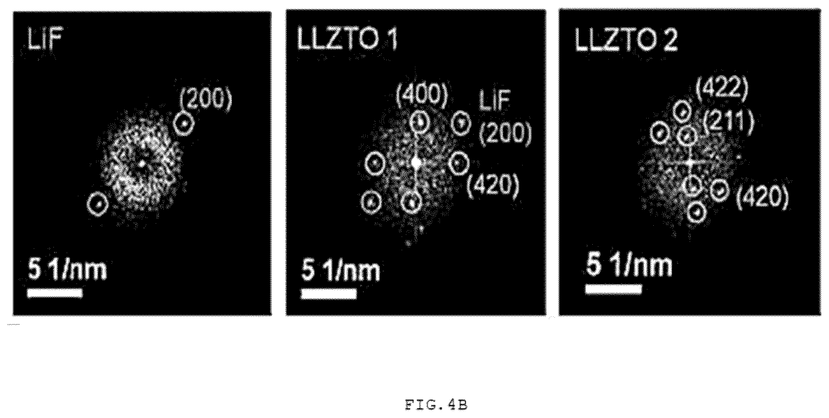

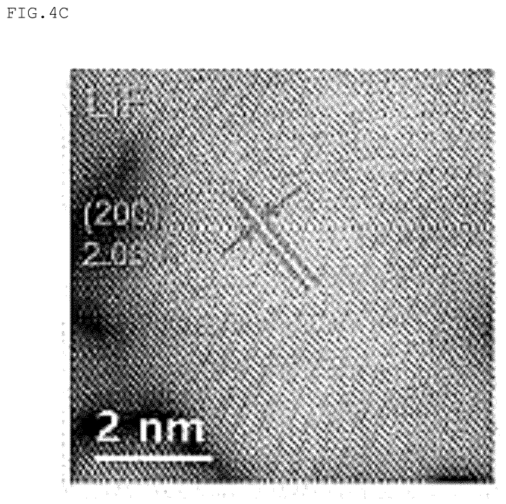

FIG. 4A is an image of high-resolution transmission electron microscopy (HRTEM) of the composite solid electrolyte layer according to Example 1. FIG. 4B is a fast Fourier transform (FFT) pattern of LiF, LLZTO region 1, and LLZTO region 2 of the composite solid electrolyte layer according to Example 1. FIG. 4C is an inverse FFT pattern of the LiF region of the composite solid electrolyte layer according to Example 1.

Referring to FIGS. 4A and 4B, it is determined that LiF is well introduced into the rough surface of LLZTO, and LLZTO regions 1 and 2 (yellow boxes) represent (211), (400), (420), and (422) crystal planes of a garnet cubic phase. In addition, LiF grains having a (200) crystal plane are clearly observed in the LLZTO region 1, and it may be inferred that the crystal plane contributed to the introduction of LiF into the rough surface of LLZTO.

Referring to FIG. 4C, it is determined that the interplanar spacing of 0.206 nm in the FFT pattern well corresponds to (200) lattice of cubic LiF

### Experimental Example 4: XPS Spectrum of Composite Solid Electrolyte Layer According to Example 1

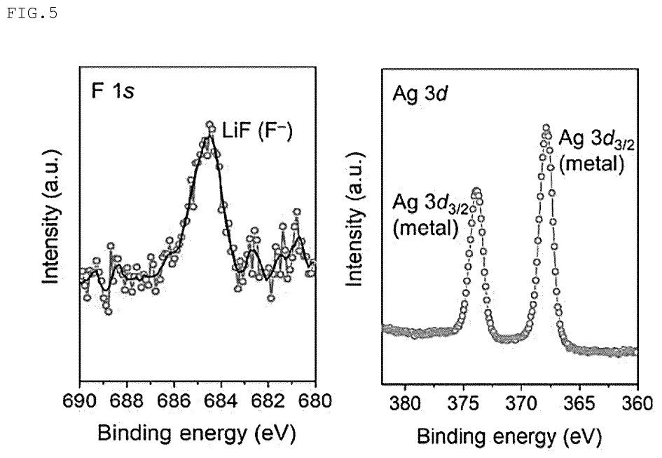

FIG. 5 shows the results of X-ray photoelectron spectroscopy (XPS) analysis of the composite solid electrolyte layer according to Example 1. To characterize the chemical composition of the multilayer, XPS (Nexsa, Thermo Fisher Scientific) analysis was performed in a condition of monochromatic Al Kα radiation (1486.6 eV) without exposure to moisture and air. The XPS spectrum was calibrated with respect to the C₁ₛ peak at 284.5 eV, corresponding to the C—C bond.

Referring to FIG. 5, it is determined that the F1s spectrum for the surface of the composite solid electrolyte layer according to Example 1 shows a characteristic peak of Li—F bonding with respect to a binding energy of 684.5 eV, and in the Ag 3d spectrum, the two peaks at 367.9 eV and 373.9 eV result from Ag 3d_{5/2} and Ag 3d_{3/2}, respectively. Accordingly, it is determined that the Ag/LiF multilayer was well formed on the surface of the LLZTO solid electrolyte.

### Experimental Example 5: Experiment Proving Electron Blocking Effect of LiF Thin Film

For DC polarization to measure the electrical conductivity of LLZTO, various voltages of 0.1 to 2.5 V were applied for 1 hour.

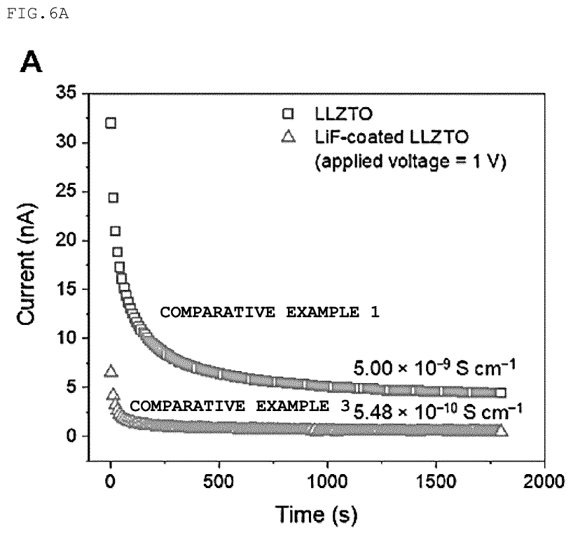

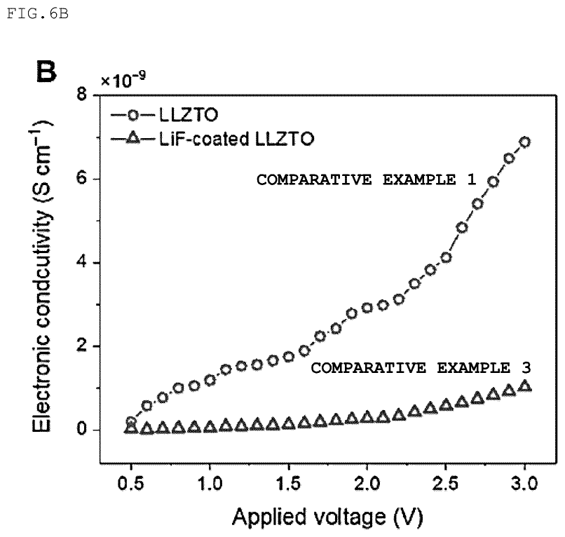

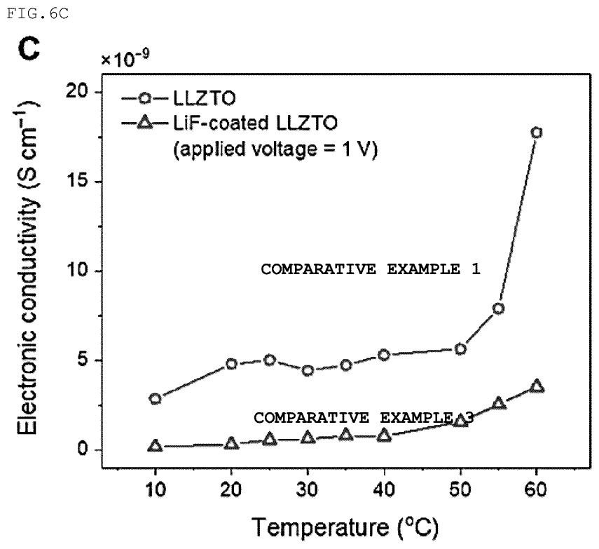

FIG. 6A is a profile of the current (mA) over time on cells including solid electrolyte layers according to Comparative Examples 1 and 3 when an applied voltage is 1 V at room temperature.

FIG. 6B is a profile of electrical conductivity (S/cm) according to voltage on cells including the solid electrolyte layers according to Comparative Examples 1 and 3.

FIG. 6C is a profile of electrical conductivity (S/cm) according to temperature on cells including the solid electrolyte layers according to Comparative Examples 1 and 3.

Referring to FIGS. 6A to 6C, it is determined that the electrical conductivity and current are reduced with the deposition of the LiF thin film on the surface of the LLZTO pellet in various conditions such as varying the voltage applied to a cell or varying the temperature. Accordingly, it is determined that the LiF thin film deposited on the surface of the LLZTO pellet brings about the effect of blocking electrons.

### Preparation Example 2: Manufacture of Lithium Symmetric Cell

To manufacture a lithium symmetric cell, lithium foil having a thickness of 300 μm and a diameter of 5 mm or 9 mm was formed on both sides of the electrolyte layer according to Preparation Example 1, and then a 2032-type coin cell was manufactured. In this case, to increase the contact between Li metal and the electrolyte layer, the cell was dried in an oven at 120° C. overnight.

### Experimental Example 6: Ex Situ BSD-SEM Image of Lithium Symmetric Cell Before and After CCD Test

For Comparative Example 2 and Example 1 among the lithium symmetric cells of Preparation Example 2 above, a critical current density (CCD) test was performed in a current density condition of 0.2 mA/cm².

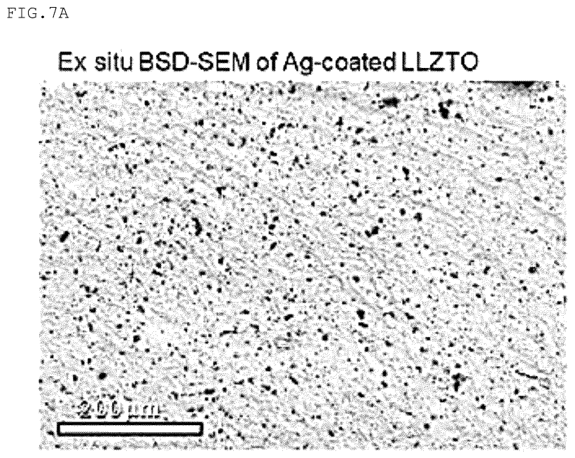

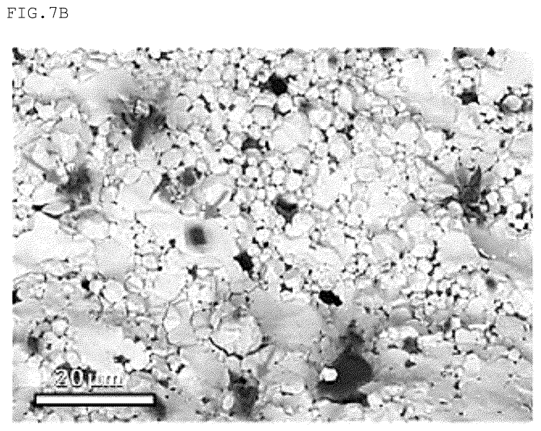

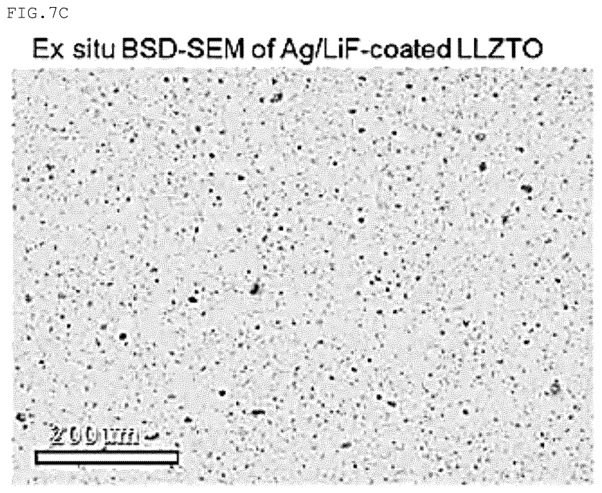

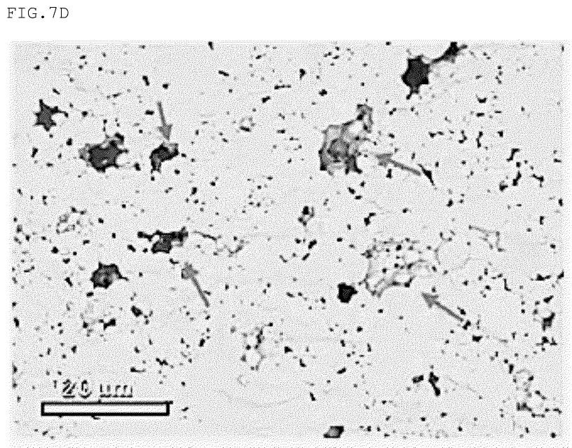

FIG. 7A is an image of ex situ backscattered electron detector (BSD)-SEM of an electrolyte layer of a lithium symmetric cell including an electrolyte layer of Comparative Example 2 before electrical short circuits. FIG. 7B is an image of ex situ backscattered electron detector (BSD)-SEM of an electrolyte layer of a lithium symmetric cell including an electrolyte layer of Comparative Example 2 after electrical short circuits.

Referring to FIGS. 7A and 7B, the bright and dark BSD images correspond to a region mainly containing elements with high atomic number (e.g., Zr and La) and a region mainly containing elements with low atomic number (e.g., Li), respectively. This may suggest potential nuclei generation of lithium metal within the cell. As shown in FIGS. 7A and 7B, it is determined that several black dots are widely distributed inside the electrolyte layer of Comparative Example 2.

FIG. 7C is an image of ex situ backscattered electron detector (BSD)-SEM of a lithium symmetric cell including an electrolyte layer of Example 1 before electrical short circuits. FIG. 7D is an image of ex situ backscattered electron detector (BSD)-SEM of a lithium symmetric cell including an electrolyte layer of Example 1 after electrical short circuits.

Referring to FIGS. 7C and 7D, in contrast to the results of FIGS. 7A and 7B, it is determined that nucleation of micro-sized lithium metal is not distributed. Accordingly, it may be inferred that the LiF thin film serving as an electron blocking layer is interposed between the lithium metal and the electrolyte layer, thereby suppressing the movement of electrons to the electrolyte layer and effectively delaying the nuclei generation of lithium metal inside the cell.

### Experimental Example 7: SEM Image of Lithium Symmetric Cell According to Example 1

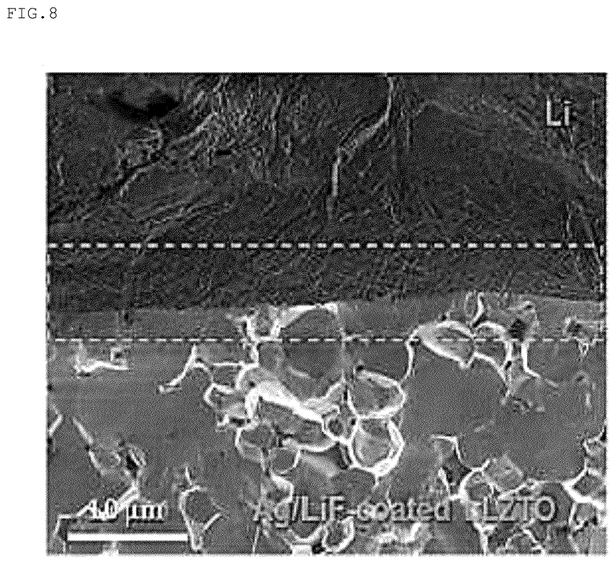

FIG. 8 is an SEM image of an interface between lithium metal and a composite solid electrolyte layer in a negative electrode-electrolyte layer assembly of Example 1.

Referring to FIG. 8, it is determined that the LiF thin film and the Ag thin film are sequentially stacked on one surface of the electrolyte, and that a micro-sized gap is not present in an interface between the electrolyte layer and the lithium metal.

### Experimental Example 8: EIS Spectrum of Lithium Symmetric Cell

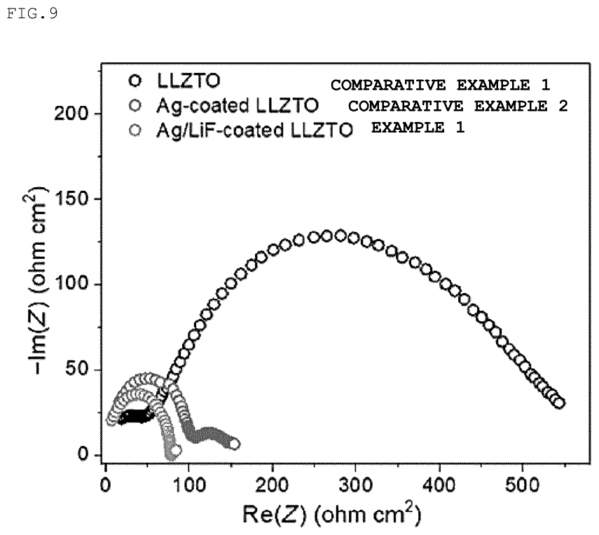

FIG. 9 is a Nyquist plot of electrochemical impedance spectroscopy (EIS) analysis for lithium symmetric cells according to Comparative Examples 1 and 2 and Example 1. Meanwhile, interfacial area specific-resistance (ASR) was determined by dividing two lithium symmetric cells, normalizing the cells to an electrode area (0.15 cm²), and then calculating fitted resistance.

Referring to FIG. 9, it is determined that by applying the Ag thin film on the LLZTO of Comparative Example 2, unlike Comparative Example 1, the interfacial area specific-resistance (ASR) is reduced, and Example 1 in which the Ag thin film and the LiF thin film are combined and applied onto the LLZTO exhibits the lowest interfacial area specific-resistance.

### Experimental Example 9: Evaluation of Electrochemical Performance of Lithium Symmetric Cell

Within the current density range of 0.1 to 3.2 mA/cm², a critical current density (CCD) test was performed on the lithium symmetric cells according to Comparative Example 2 and Example 1 at 60° C. while increasing the current density stage by stage by 0.1 mA/cm².

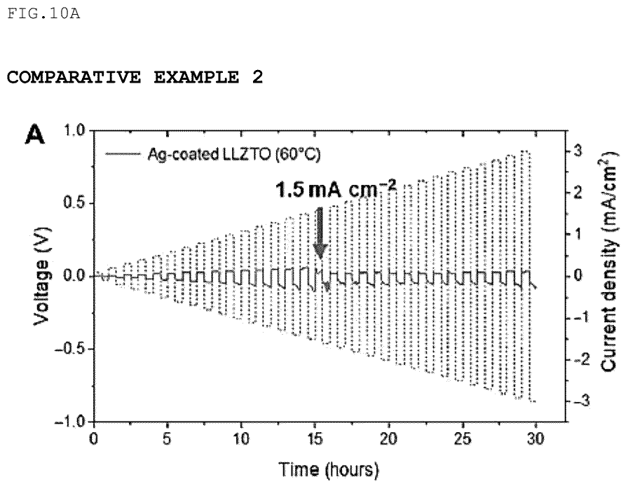

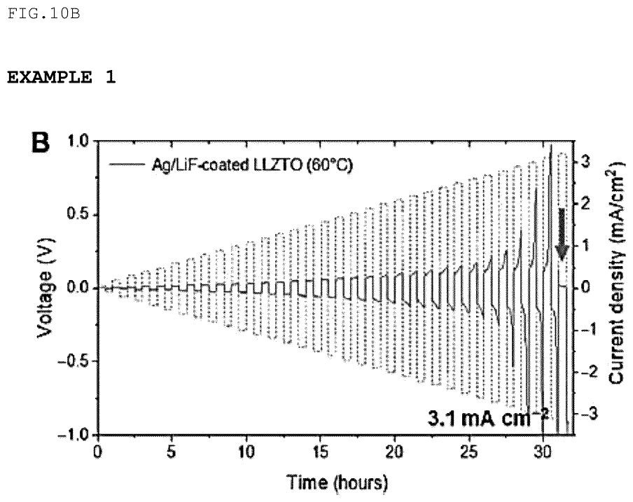

FIG. 10A shows critical current density of a lithium symmetric cell of Comparative Example 2 with an increase in current density.

FIG. 10B shows critical current density of a lithium symmetric cell of Example 1 with an increase in current density.

Referring to FIGS. 10A and 10B, it is determined that Example 1 maintains low polarization even at high current density, thereby exhibiting a high critical current density of 3.1 mA/cm², which is significantly higher than that of Comparative Example 2. Accordingly, it may be inferred that the lithium symmetric cell of Example 1 had improved stability through the combining of the electron blocking layer and the lithiophilic layer.

### Experimental Example 10: Evaluation of Cycle Performance of Lithium Symmetrical Cell

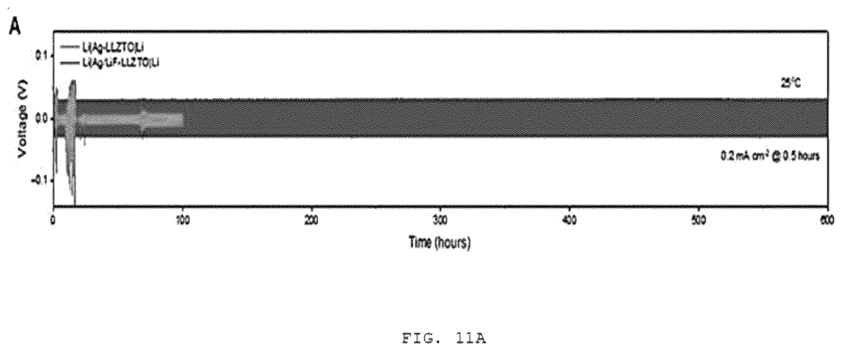

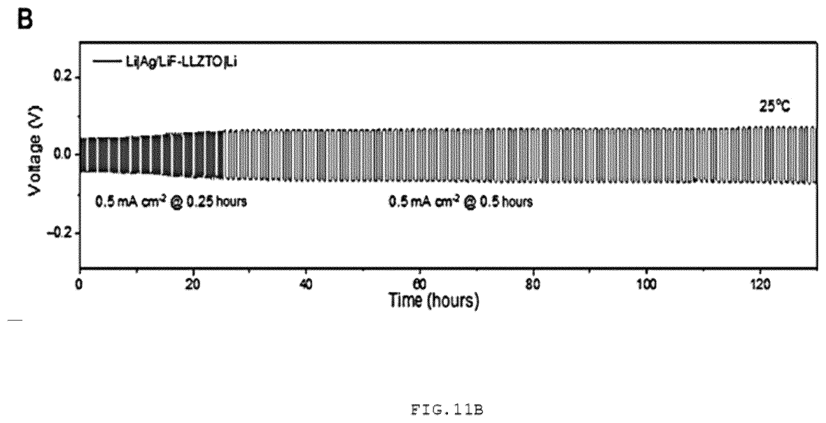

FIG. 11A shows the results of cycle stability evaluation according to constant current charge/discharge method on the lithium symmetric cells of Comparative Example 2 and Example 1 when the current density is 0.2 mA/cm² for 0.5 hours at 25° C. Constant current tests were measured using potentio-galvanostat (WBCS 3000, WonATech).

Referring to FIG. 11A, it is determined that the lithium symmetric cell of Example 1 shows remarkably solid stability for 600 hours without a significant increase in overpotential during intercalation/deintercalation of lithium whereas the lithium symmetric cell of Comparative Example 2 shows cell degradation after dozens of cycles.

FIG. 11B shows the results of cycle stability evaluation according to constant current charge/discharge method on the lithium symmetric cell of Example 1 when the current density is 0.5 mA/cm² at 25° C.

Referring to FIG. 11B, it is determined that the lithium symmetric cell of Example 1 exhibits stable cycle performance for 130 hours or more at a high current density of 0.5 mA/cm² while maintaining the overpotential below 0.1 V.

### Preparation Example 3: Preparation of Hybrid Full Cell

### Preparation of Positive Electrode

A positive electrode slurry in which an LiFePO₄ (LFP) positive electrode active material, Super P, and N-methyl-2-pyrrolidone (solvent) were mixed at a weight ratio of 80:10:10 was applied onto aluminum foil (positive electrode current collector) and dried in an oven of 70 É overnight to prepare a preliminary positive electrode. In this case, the positive electrode active material has a loading amount of 3 to 3.5 mg/cm². An ionic liquid (2M LiFSI in N-propyl-N-methylpyrrolidinium bis(fluorosulfonyl)imide) was impregnated into the prepared preliminary positive electrode to finally prepare a positive electrode.

### Preparation of Negative Electrode-Solid Electrolyte Layer Assembly

Lithium metal (negative electrode) having a thickness of 20 μm was disposed on one surface of the solid electrolyte layer according to Preparation Example 1 above, and then 25 É to 250 MPa was applied using cold isotactic pressing (CIP) to prepare a negative electrode-solid electrolyte layer assembly.

### Preparation of Full Cell

A positive electrode layer was disposed inside an SUS cap so that a positive electrode active material layer was toward an upper end. The negative electrode-solid electrolyte layer assembly was disposed so that the solid electrolyte layer according to Preparation Example 1 above was disposed on the positive electrode active material layer, and then sealed to finally manufacture an all-solid secondary battery in the form of a full cell.

### Experimental Example 11: Evaluation of Cycle Stability of Hybrid Full Cell

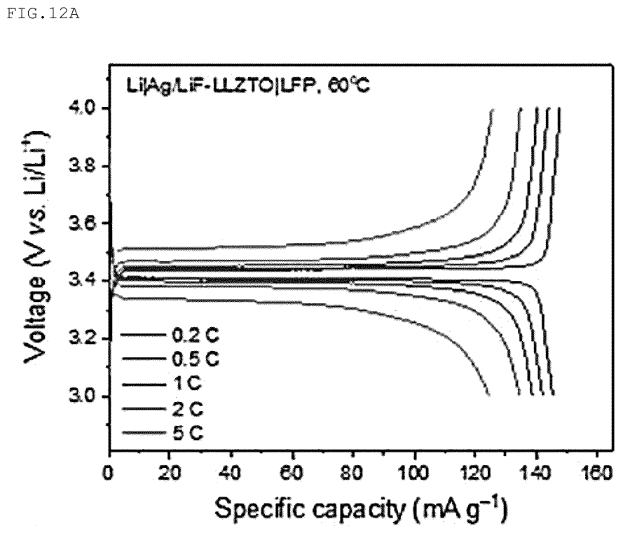

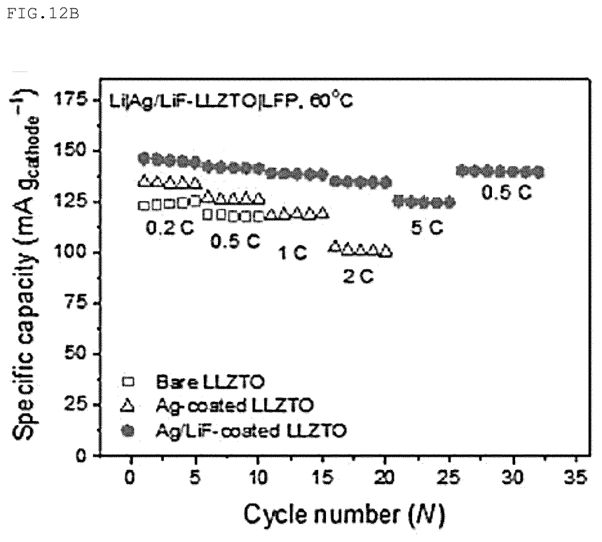

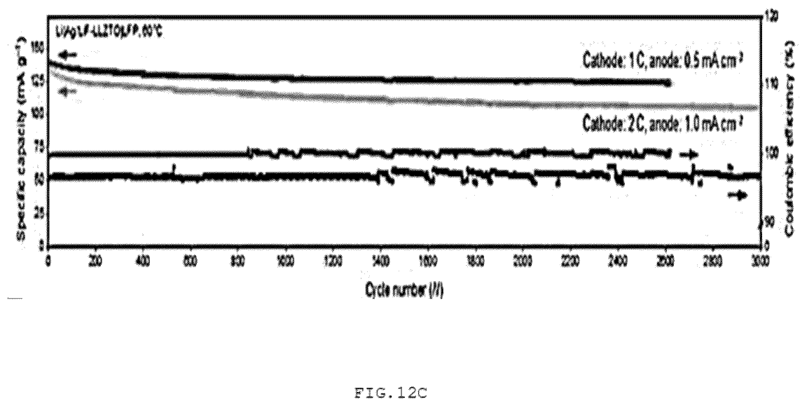

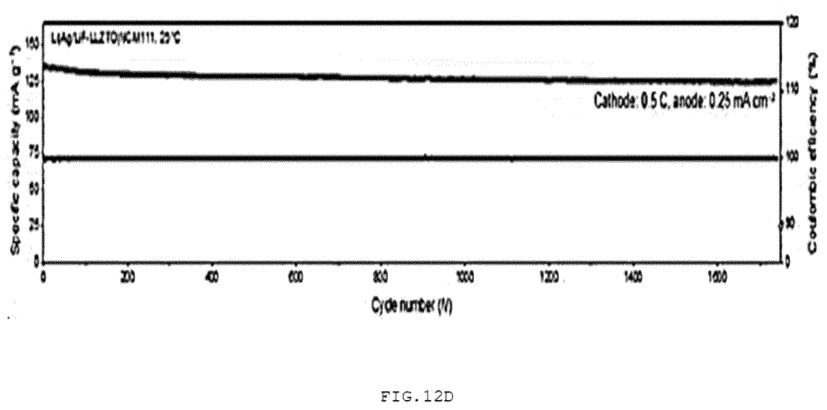

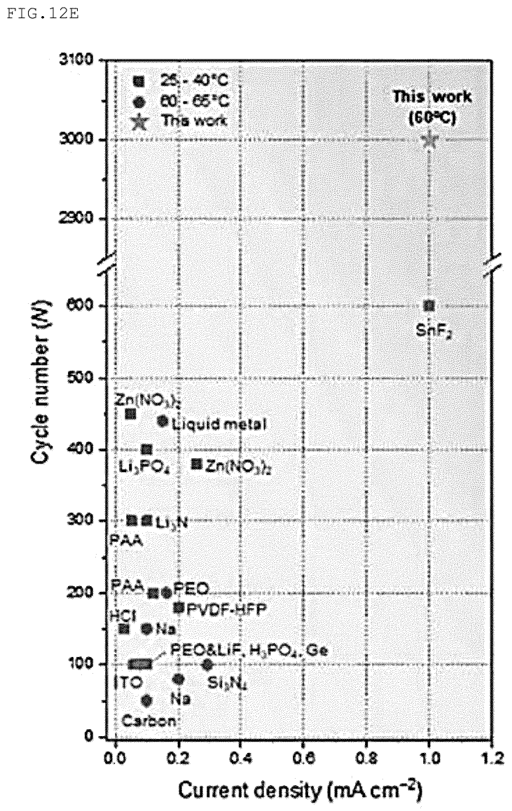

FIG. 12A is a voltage profile according to specific capacity on a hybrid full cell of Example 1 at 60° C. when the charge/discharge rate (C-rate) is different.

Referring to FIG. 12A, it is determined that the hybrid full cell of Example 1 provides appropriate power performance. Specifically, it is determined that even when the charge/discharge rate is increased to 5 C, a specific capacity of 124.7 mA·h/g is achieved.

FIG. 12B shows specific capacity (mA·h/g) according to the number of cycles on hybrid full cells of Comparative Examples 1 and 2 and Example 1 at 60° C. when the charge/discharge rate (C-rate) is different.

Referring to FIG. 12B, it is determined that the hybrid full cells of Comparative Examples 1 and 2 showed generally low discharge capacity due to early degradation of the cell with the growing number of charge/discharge cycles, and failed to work in a range greater than 0.5 C. It may be assumed that the early degradation of the hybrid full cells of Comparative Examples 1 and 2 was caused by the high current density applied to the lithium metal (negative electrode) exceeding the critical current density of the electrolyte layer. On the other hand, it is determined that the hybrid full cell of Example 1 has an increased critical current density of the electrolyte layer to prevent degradation even when a high current density is applied to the lithium metal (negative electrode), and the cell maintains specific capacity at the same level as the initial level even when the number of cycles increases.

FIG. 12C shows cycle performance of the hybrid full cell of Example 1 when 1.0 C is applied to a positive electrode and 0.5 mA/cm² (yellow & dark gray) is applied to a negative electrode, and 2.0 C is applied to a positive electrode and 1.0 mA/cm² (green & light gray) is applied to a negative electrode.

For experiment of FIG. 12D, a cell was manufactured in the same manner as the hybrid full cell of Example 1, but ‘Modified Example 1’ was manufactured using an NCM111 positive electrode instead of LFP.

FIG. 12D shows cycle performance of a hybrid full cell of modified Example 1 when 0.5 C is applied to a positive electrode and 0.25 mA/cm² is applied to a negative electrode.

Referring to FIGS. 12C and 12D, it is determined that the hybrid full cells of Example 1 and Modified Example 1 maintain the specific capacity at the same level as the initial level even when the number of cycles increases and have excellent cycle stability.

FIG. 12E compares a typical hybrid full cell and the hybrid full cell of Example 1.

Referring to FIG. 12E, it is determined that the hybrid full cell of Example 1 has excellent speed characteristics compared to the typical hybrid full cell, and also has excellent cycle durability for a long period of time.

Summarizing the above experimental results, the Ag/LiF multilayer may contribute equalizing the interface characteristics between the electrolyte layer and the electrode during charge/discharge, effectively preventing the generation of leakage current through the cell, and ensuring that the cell works well even at high current densities.

While preferred embodiments of the present invention have been described in detail, the invention is not limited to the disclosed embodiments. On the contrary, those skilled in the art will appreciate that various modifications and changes may be made without departing from the spirit and scope of the present invention as set forth in the following claims.

1. A composite solid electrolyte layer comprising:
a solid electrolyte layer comprising a solid electrolyte;
an electron blocking layer disposed on at least one surface of the solid electrolyte layer; and
a lithiophilic layer disposed on the electron blocking layer.

2. The composite solid electrolyte layer of claim 1, wherein the solid electrolyte is at least any one selected from an oxide-based solid electrolyte and a sulfide-based solid electrolyte.

3. The composite solid electrolyte layer of claim 2, wherein the oxide-based solid electrolyte is at least one selected from Li_{1+x+y}AlₓTi₂₋ₓSi_{y}P_{3-y}O12 (0<x<2, 0>y<3), Li₃PO₄, LiₓTi_{y}(PO₄)₃ (0<x<2, 0<y<3), LiₓAl_{y}Ti_{z}(PO₄)₃ (0<x<2, 0<y<1, 0<z<3), Li_{1+x+y}(Al, Ga)ₓ (Ti, Ge)₂₋ₓSi_{y}P_{3-y}O₁₂ (0≤x≤1 0=y≤1), LiₓLa_{y}TiO₃ (0<x<2, 0<y<3) , Li₂O, LiOH, Li₂CO₃, LiAlO₂, Li₂O—Al₂O₃—SiO₂—P₂O₅—TiO₂—GeO₂, and Li₃₊ₓLa₃M₂O₁₂ (M=Te, Nb, or Zr, and x is an integer of 1 to 10).

4. The composite solid electrolyte layer of claim 2, wherein the oxide-based solid electrolyte comprises a garnet-type solid electrolyte.

5. The composite solid electrolyte layer of claim 4, wherein the garnet-type solid electrolyte comprises a compound represented by Formula 1 below:
(LiₓM1_{y})(Laₐ₁M2ₐ₂)_{3-δ}(Zr_{b1}M3_{b2})_{2-ω}O_{12-z}X_{z} [Formula 1]
wherein in Formula 1 above,
M1 is any one selected from the group consisting of hydrogen (H), iron (Fe), gallium (Ga), aluminum (Al), boron (B), beryllium (Be), and a combination thereof,
M2 is any one selected from the group consisting of barium (Ba), calcium (Ca), strontium (Sr), yttrium (Y), bismuth (Bi), praseodymium (Pr), neodymium (Nd), actinium (Ac), samarium (Sm), gadolinium (Gd), and a combination thereof,
M3 is any one selected from the group consisting of hafnium (Hf), tin (Sn), niobium (Nb), titanium (Ti), vanadium (V), chromium (Cr), manganese (Mn), cobalt (Co), nickel (Ni), copper (Cu), molybdenum (Mo), tungsten (W), tantalum (Ta), magnesium (Mg), technetium (Tc), ruthenium (Ru), palladium (Pd), iridium (Ir), scandium (Sc), cadmium (Cd), indium (In), antimony (Sb), tellurium (Te), thallium (Tl), platinum (Pt), silicon (Si), aluminum (Al), and a combination thereof, and
6≤x≤8, 0≤y<2, −0.2≤δ≤0.2, −0.2≤ω≤0.2, and 0≤z≤2 are satisfied, a1+a2=1, 0<a1≤1, 0≤a2<1, b1+b2=1, 0<b1<1, and 0<b2<1 are satisfied, and X is a monovalent anion, a divalent anion, or a trivalent anion.

6. The composite solid electrolyte layer of claim 4, wherein the garnet-type solid electrolyte comprises a compound represented by Formula 2 below:
Li₃₊ₓLa₃Zr₂₋ₐMₐO₁₂ [Formula 2]
wherein in Formula 2 above,
M is any one selected from the group consisting of Al, Ga, In, Si, Ge, Sn, Sb, Bi, Sc, Y, Ti, Hf, V, Nb, Ta, W, and a combination thereof,
x is an integer of 1 to 10, and
0≤a<2 is satisfied.

7. The composite solid electrolyte layer of claim 2, wherein the sulfide-based solid electrolyte comprises at least one selected from Li₂S—P₂S₅, Li₂S—P₂S₅—Li_{X} (where X is a halogen element), Li₂S—P₂S₅—Li₂O, Li₂S—P₂S₅—Li₂O—LiI, Li₂S—SiS₂, Li₂S—SiS₂—LiI, Li₂S—SiS₂—LiBr, Li₂S—SiS₂—LiCl, Li₂S—SiS₂—B₂S₃—LiI, Li₂S—SiS₂—P₂S₅—LiI, Li₂S—B₂S₃, Li₂SP₂S₅—ZₘSₙ (where m and n are positive numbers, and Z is one of Ge, Zn, or Ga), Li₂S—GeS₂, Li₂S—SiS₂—Li₃PO₄, Li₂S—SiS₂—LiₚMO_{q} (where p and q are positive numbers, and M is one of P, Si, Ge, B, Al, Ga, or In), Li₇₋ₓPS₆₋ₓClₓ (0<x<2), Li₇₋ₓPS₆₋ₓBrₓ (0<x<2), and Li₇₋ₓPS₆₋ₓIₓ (0<x<2).

8. The composite solid electrolyte layer of claim 1, wherein the electron blocking layer comprises an inorganic compound.

9. The composite solid electrolyte layer of claim 8, wherein the inorganic compound comprises at least any one selected from the group consisting of a halide-based compound and a metal oxide.

10. The composite solid electrolyte layer of claim 9, wherein the halide-based compound is at least one or at least two selected from the group consisting of LiF, NaF, KF, RbF, CsF, FrF, MgF₂, CaF₂, SrF₂, BaF₂, LiCl, NaCl, KCl, RbCl, CsCl, and FrCl.

11. The composite solid electrolyte layer of claim 9, wherein the metal oxide is at least one or at least two selected from the group consisting of Li₂O, Li₂O₂, Na₂O, K₂O, Rb₂O, Rb₂O₂, CS₂O, CS₂O₂, LiAlO₂, LiBO₂, LiTaO₃, LiNbO₃, LiWO₄, Li₂CO, NaWO₄, KAlO₂, K₂SiO₃, B₂O₅, Al₂O₃, and SiO₂.

12. The composite solid electrolyte layer of claim 1, wherein the electron blocking layer has a thickness of 10 to 200 nm.

13. The composite solid electrolyte layer of claim 1, wherein the lithiophilic layer comprises a lithium alloy forming material.

14. The composite solid electrolyte layer of claim 13, wherein the lithium alloy forming material comprises one selected from the group consisting of silver (Ag), gold (Au), aluminum (Al), calcium (Ca), zinc (Zn), magnesium (Mg), and potassium (K), a mixture of two or more thereof, or an alloy of two or more thereof.

15. The composite solid electrolyte layer of claim 1, wherein lithium diffusivity in the lithiophilic layer is 10⁻¹⁰ cm²/s or greater at 25° C.

16. The composite solid electrolyte layer of claim 1, wherein lithium diffusivity in the lithiophilic layer is 10⁻⁶ cm²/s or greater at 25° C.

17. The composite solid electrolyte layer of claim 1, wherein the lithiophilic layer has a thickness of 10 to 200 nm.

18. A method for preparing a composite solid electrolyte layer, the method comprising:
(S1) forming an electron blocking layer on at least one surface of a solid electrolyte layer comprising a solid electrolyte; and
(S2) forming a lithiophilic layer on one surface of the electron blocking layer of the solid electrolyte layer on which the electron blocking layer is formed.

19. The method of claim 18, wherein (S1) and (S2) above are performed through the same deposition process or different deposition processes.

20. The method of claim 18, wherein (S1) and (S2) above are each independently performed through any one method selected from the group consisting of physical vapor deposition, chemical vapor deposition, and a combination thereof.

21. The method of claim 18, wherein (S1) and (S2) above are performed through a process of thermal evaporation deposition.

22. The method of claim 18, wherein (S1) and (S2) above each independently comprise:
depositing at least any one thin film of the electron blocking layer and the lithiophilic layer at a deposition rate of 0.1 to 1.0 Ås⁻¹; and
annealing the deposited thin film at 400 to 800° C. for 1 to 3 hours.

23. An all-solid secondary battery comprising:
a composite solid electrolyte layer according to claim 1;
a negative electrode disposed on one surface of the composite solid electrolyte layer; and
a positive electrode disposed on the other surface of the composite solid electrolyte layer,
wherein the negative electrode is in contact with the lithiophilic layer.
